(19) United States
(12) Patent Application Publication
(10) Pub. No.: US 2025/0385206 A1
(43) Pub. Date: Dec. 18, 2025

(54) CONFIGURING CONDUCTIVE SEPARATING STRUCTURES BETWEEN DIES AND SUBSTRATES

(71) Applicant: Ciena Corporation, Hanover, MD (US)

(72) Inventors: Simon Savard, Quebec (CA); Luc Bélanger, Quebec (CA)

(73) Assignee: Ciena Corporation, Hanover, MD (US)

(21) Appl. No.: 18/742,288

(22) Filed: Jun. 13, 2024

(51) Int. Cl. H01L 23/00

(52) U.S. Cl. CPC H01L 24/13; H01L 24/05; H01L 24/16; H01L 24/81; H01L 2224/05144; H01L 2224/13082; H01L 2224/13147; H01L 2224/13611; H01L 2224/16227; H01L 2224/81815; H01L 2924/10335

(57) ABSTRACT

In one aspect, in general, an apparatus comprises: a die having a surface over which one or more metal contacts are arranged and over which one or more contact-sensitive structures are arranged; a plurality of conductive separating structures, each of the conductive separating structures (1) comprising two or more stud bumps, and (2) having a first stud bump of the two or more stud bumps in contact with at least one of the one or more metal contacts; a conductive paste coating a portion of each of the conductive separating structures including at least a portion of a second stud bump of the two or more stud bumps; and a substrate abutting the conductive paste at an end of the second stud bump.

### TECHNICAL FIELD

This disclosure relates to configuring conductive separating structures between dies and substrates.

### BACKGROUND

Chip-scale devices comprising integrated circuits remain a vital component in applications ranging from electronics to optical connectivity. Increasing demand for these chip-scale devices has led to advancements not only in their operating capabilities, physical requirements, and reliability, but also in the optimization of their manufacturing processes including production and testing. Some implementations of chip-scale devices comprise a die connected to external circuitry that controls the device. Such implementations necessitate highly repeatable and reliable device manufacturing techniques that can produce connections between the die and external circuitry. Controlled collapse chip connection (C4), also known as flip chip, has emerged as a packaging technique that enables device miniaturization and performance, while also reducing manufacturing overheads. In a typical flip chip assembly, integrated circuits and metal contacts are first distributed over the surface of a die. Next, solder is deposited onto the metal contacts and the semiconductor die is “flipped” onto a substrate with external circuity. The solder is then heated to bond the die and the substrate together.

### SUMMARY

In one aspect, in general, an apparatus comprises: a die having a surface over which one or more metal contacts are arranged, where the surface is substantially coplanar with a first plane; a conductive separating structure with a first end in contact with at least one of the one or more metal contacts, the conductive separating structure extending away from the first end along an axis that is substantially perpendicular to the first plane and (1) intersecting a second plane that is substantially parallel to the first plane at a first location along the axis such that an intersection of the conductive separating structure with the second plane forms a first curve enclosing a first area, and (2) intersecting a third plane that is substantially parallel to the first plane at a second location along the axis that is further from the first plane than from the second plane, such that an intersection of the conductive separating structure with the third plane forms a second curve enclosing a second area, wherein the first area is smaller than the second area; a conductive paste coating a portion of the conductive separating structure between the second plane and a second end of the conductive separating structure and not between the second plane and the first plane; and a substrate having a surface that is substantially parallel to the first plane, the substrate abutting the conductive paste at the second end of the conductive separating structure.

Aspects can include one or more of the following features.

The conductive separating structure intersects a fourth plane that is substantially parallel to the first plane at a third location along the axis that is between the first plane and the first location such that an intersection of the conductive separating structure with the fourth plane forms a third curve enclosing a third area that is larger than the first area.

The apparatus further comprises a plurality of conductive separating structures such that each of the one or more metal contacts is in contact with a first end of at least one of the plurality of conductive separating structures.

One or more contact-sensitive structures are arranged on the surface of the die.

At least one of the one or more contact-sensitive structures has a first portion contacting the surface of the die and a second portion suspended in an air gap between the surface of the die and the surface of the substrate.

A portion of the conductive separating structure that is not coated in conductive paste is surrounded by air.

One or more of the metal contacts comprises gold.

The die comprises indium phosphide.

The conductive separating structure comprises copper.

The conductive paste comprises one or more metals that include tin.

The conductive paste does not include lead.

The conductive paste comprises one or more materials that do not cause embrittlement of any material in the conductive separating structure and that do cause embrittlement of at least one material in the one or more metal contacts.

The die and the substrate each have a coefficient of thermal expansion (CTE), and the CTE of the substrate and the CTE of the die are within 10% of each other.

In another aspect, in general, a method of connecting a die and a substrate comprises: arranging one or more metal contacts over a surface of the die, where the surface is substantially coplanar with a first plane; placing a first end of a conductive separating structure into contact with one or more of the metal contacts, the conductive separating structure extending away from the first end along an axis that is substantially perpendicular to the first plane and (1) intersecting a second plane that is substantially parallel to the first plane at a first location along the axis such that an intersection of the conductive separating structure with the second plane forms a first curve enclosing a first area, and (2) intersecting a third plane that is substantially parallel to the first plane at a second location along the axis that is further from the first plane than from the second plane, such that an intersection of the conductive separating structure with the third plane forms a second curve enclosing a second area, wherein the first area is smaller than the second area; applying conductive paste onto a surface of the substrate; aligning the surface of the substrate to be substantially parallel to the surface of the die, and contacting a second end of the conductive separating structure to the conductive paste; and coating the conductive separating structure with the conductive paste such that the conductive paste coats a portion of the conductive separating structure between the second end and the second plane and not between the second plane and the first plane.

Aspects can include one or more of the following features.

The conductive separating structure comprises two or more copper stud bumps.

The conductive separating structure causes the surface of the die and the surface of the substrate to be separated by an air gap.

A contact-sensitive structure on the surface of the die is suspended in the air gap.

Each of the one or more metal contacts is placed into contact with at least one conductive separating structure of a plurality of conductive separating structures.

Coating the conductive separating with the conductive paste comprises heating the conductive paste.

The method further comprises forming one or more contact-sensitive structures on the surface of the die prior to coating the conductive separating structure with the conductive paste.

In another aspect, in general, an apparatus comprises: a die having a surface over which one or more metal contacts are arranged and over which one or more contact-sensitive structures are arranged; a plurality of conductive separating structures, each of the conductive separating structures (1) comprising two or more stud bumps, and (2) having a first stud bump of the two or more stud bumps in contact with at least one of the one or more metal contacts; a conductive paste coating a portion of each of the conductive separating structures including at least a portion of a second stud bump of the two or more stud bumps; and a substrate abutting the conductive paste at an end of the second stud bump.

Aspects can include one or more of the following features.

At least one of the one or more contact-sensitive structures has a first portion contacting the surface of the die and a second portion suspended in an air gap between the surface of the die and a surface of the substrate.

A portion of each of the conductive separating structures that is not coated in conductive paste is surrounded by air.

One or more of the metal contacts comprises gold.

The die comprises indium phosphide.

The conductive separating structures comprise copper.

The conductive paste comprises one or more metals that include tin.

The conductive paste does not include lead.

The conductive paste comprises one or more materials that do not cause embrittlement of any material in the conductive separating structures and that do cause embrittlement of at least one material in the one or more metal contacts.

The die and the substrate each have a coefficient of thermal expansion (CTE), and the CTE of the substrate and the CTE of the die are within 10% of each other.

Aspects can have one or more of the following advantages.

The methods and systems of flip chips disclosed herein comprise a conductive separating structure joining a die (e.g., a semiconductor die) and a substrate (e.g., another die). The conductive separating structure can comprise a double stud bump produced by forming a first sphere-like metal structure (also referred to as a stud bump) and depositing the sphere-like metal structure onto the die, then forming and depositing another sphere-like metal structure on top of the first sphere-like metal structure. In some examples, more than two stud bumps can be used. Conductive separating structures such as the double stud bump structures disclosed herein can allow for fragile structures to be situated on the surface of the die without the risk of contamination and damage that might arise from standard manufacturing techniques, such as wet cleaning or underfill processes. Further, the double stud bump structures disclosed herein can lower the risk of embrittlement arising from the contact and reaction of incompatible materials, such as lead-free solder paste and gold. The methods and systems disclosed herein can also allow for more compact device footprints and enhanced process validation compared to other chip packaging technologies, such as wirebonding. For instance, the flip chip arrangement described herein can allow for batch failure processing of solder connections.

Other features and advantages will become apparent from the following description, and from the figures and claims.

### BRIEF DESCRIPTION OF THE DRAWINGS

The disclosure is best understood from the following detailed description when read in conjunction with the accompanying drawings. It is emphasized that, according to common practice, the various features of the drawings are not to-scale. On the contrary, the dimensions of the various features are arbitrarily expanded or reduced for clarity.

FIG. 1 is a schematic diagram of an example of a conductive separating structure assembly.

FIG. 2 is a schematic diagram of an example of a stud bump assembly.

FIG. 3 is a schematic diagram of an example of an integrated circuit flip chip device.

FIG. 4 is a flowchart of an example process for connecting a die and a substrate.

### DETAILED DESCRIPTION

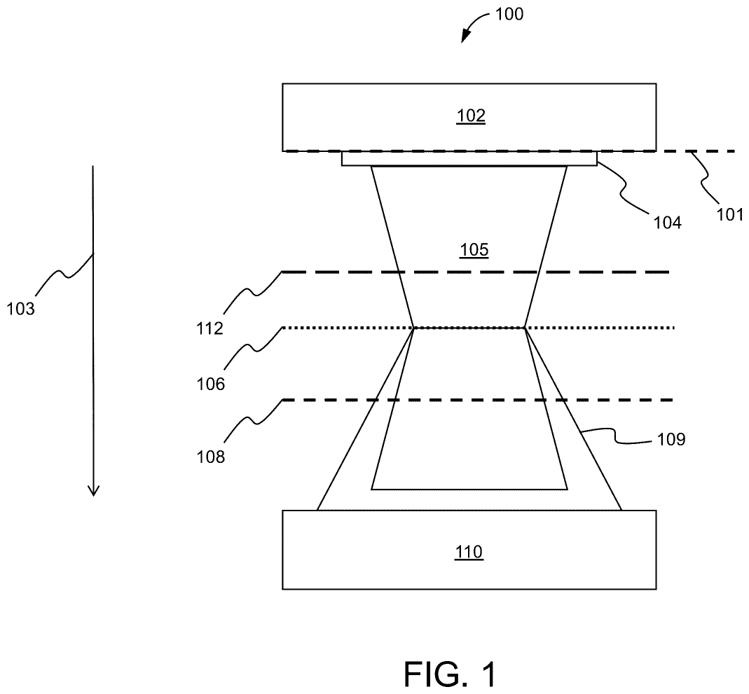

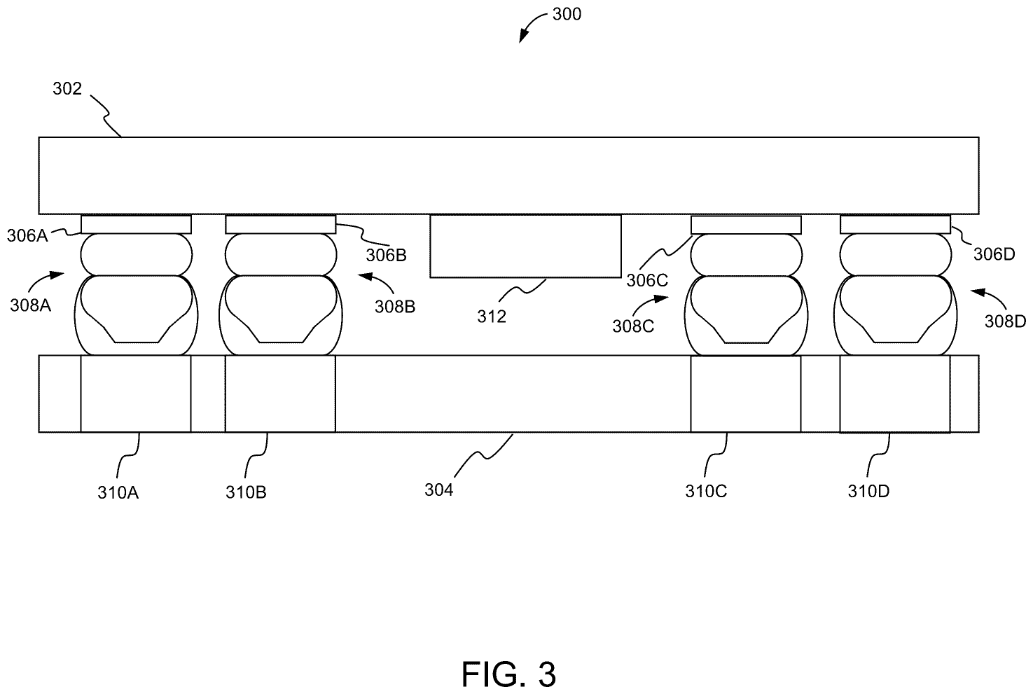

Referring to FIG. 1, some integrated circuit devices can include an assembly 100 comprising a metal contact 104 arranged on the surface of a die 102 that is substantially coplanar with a first plane 101 (extending into the page). A first end of a conductive separating structure 105 can be placed into contact with the metal contact 104 while a second end of the conductive separating structure 105 can extend along an axis 103 perpendicular to the first plane toward a substrate 110 and form a conductive connection to a surface of the substrate 110 using a conducting paste 109. In this example, the metal contact 104 and a contacting surface of the first end of the conductive separating structure 105 are parallel and are attached to each other by techniques that can use temperature and/or mechanical (e.g., ultrasonic) forces to create a robust metallic joint by solid state diffusion or the creation of intermetallic compounds (IMCs) upon the elements in contact. This technique, also called wirebonding or stud bumping, is performed individually on each metal contact 104 and does not affect any surrounding fragile structures. With such an individual process, the force needed to ensure the first end of the conductive separating structure 105 stays in contact with the metal contact 105 can be kept relatively low (e.g., approximately 20 grams for each structure). However, after many such conductive separating structures are placed onto metal contacts on the surface of the die 102, the higher total force that would be needed to attach the second end to the substrate 110 could potentially result in damage to fragile or otherwise contact-sensitive structures on the die 102. Certain other techniques for contacting the conductive separating structures on the die 102 to the substrate 110, where the whole substrate 110 would be coated with metals and photoresist, immerge into liquid solutions for electroplating, stripping, etching and cleaning could also result in damage to the fragile structures. So instead, a technique can be used to form an electrical connection using the conductive paste 109 in a manner that ensures that the conductive paste 109 will not migrate far enough to reach the metal contact 104, which could damage the metal contact 104 (e.g., due to gold embrittlement). The conductive separating structure 105 intersects a second plane 106 that is substantially parallel to the first plane 101 at a first location along the axis 103 to form a first curve that encloses a first area. The conductive separating structure 105 also intersects a third plane 108 that is substantially parallel to the first plane 101 at a second location along the axis 103 such that a second curve enclosing a second area is formed. The first area is smaller than the second area such that the conductive paste 109 coating the second end of the conductive separating structure 105 can extend up to but not further than the first location. The conductive separating structure 105 further intersects a fourth plane 112 between the first plane 101 and the first location to form a third curve that encloses a third area that is larger than the first area. For clarity of illustration, only a portion of each of the die 102 and the substrate 110 are shown, but each can extend further to the left and right to allow for more conductive separating structures as shown in FIG. 3.

The assembly depicted in FIG. 1 can be produced by a flip chip process, wherein a metal contact is arranged on the surface of the die 102 and the conductive separating structure 105 is attached to the metal contact 104. The conductive paste 109 is then deposited on the surface of the substrate 110 and the conductive separating structure 105 is brought into contact with the conductive paste 109. The conductive paste 109 is heated such that it coats the conductive separating structure 105. This process is helpful to avoid techniques that place conductive paste on the metal contact 104, which may have necessitated a wet cleaning step to remove excess conductive paste that might have accumulated on the surface of the die 102. The non-cylindrical shape of the conductive separating structure 105 can help to ensure that the flow of the conductive paste is controlled to end at a narrower portion of the conductive separating structure 105 and provide an area surrounding the conductive separating structure 105 between the first plane 101 and the second plane 106 that is devoid of any conductive paste.

In some examples of the assembly shown in FIG. 1, the metal contact on the surface of the die 102 can comprise an outer layer of gold and the conductive paste can comprise tin and/or a number of other metals. In some examples, the conductive paste is a lead-free solder paste (i.e., does not contain any lead). With such a combination, gold embrittlement can occur if the lead-free solder paste encounters the gold contact, which can result in failure of the connection and ultimately device malfunction. Varying the geometry of the conductive separating structure along its length, as shown in FIG. 1, can help prevent the lead-free solder paste from reaching the gold contact, lowering the risk of gold embrittlement and device failure.

Some integrated circuit devices can comprise fragile structures on the die 102, such as structures configured to guide optical waves, or any other contact-sensitive structures having a function that is vulnerable to impairment by deformation arising from contact or proximity to other structures and/or materials. Such contact-sensitive structures may be distributed on the surface of the die 102. These contact-sensitive structures can comprise optical waveguides, modulators, Mach-Zender interferometers, multi-dimensional photonic circuits, micro-electro-mechanical systems, or some combination thereof. Without the techniques described herein, these contact-sensitive structures could be damaged or contaminated during certain fabrication processes (e.g., a wet cleaning process). In addition, the function of some of these contact sensitive structures can be inhibited if the structure is placed in contact with another material, for instance a material occupying the gap between the die 102 and the substrate 110. In the assembly depicted in FIG. 1, an air gap is formed between the surface of the die 102 and the substrate 110. Contact-sensitive structures attached to the surface of the die 102 can be suspended in this air gap, potentially preventing damage and disfunction of the structure.

Some integrated circuit devices produced by flip chip techniques can incorporate a material layer between the die and the substrate to improve device integrity. The mechanical stress experienced by a flip chip device can depend upon the coefficient of thermal expansion (CTE) of the materials comprising the die and the substrate. Large CTE mismatches can result in stress to the flip chip assembly, potentially leading to low reliability and malfunction of the device. In some implementations, a material such as a polymer adhesive can be injected into the gap between the die and substrate such that the gap is “underfilled” to rectify the CTE mismatch and reduce stress. However, this underfill technique can damage any contact-sensitive structures on the surface of a die. To prevent or reduce mechanical stress in a flip chip with an air gap between the die and the substrate, careful selection of die and substrate materials with matching CTEs is used in some implementations. For example, the CTE of the die and the CTE of the substrate can be within 10% of each other or closer (e.g., within 5% or within 2%). An example of a material that can be used for the die is indium phosphide. An example of a material that can be used for the substrate is ceramic.

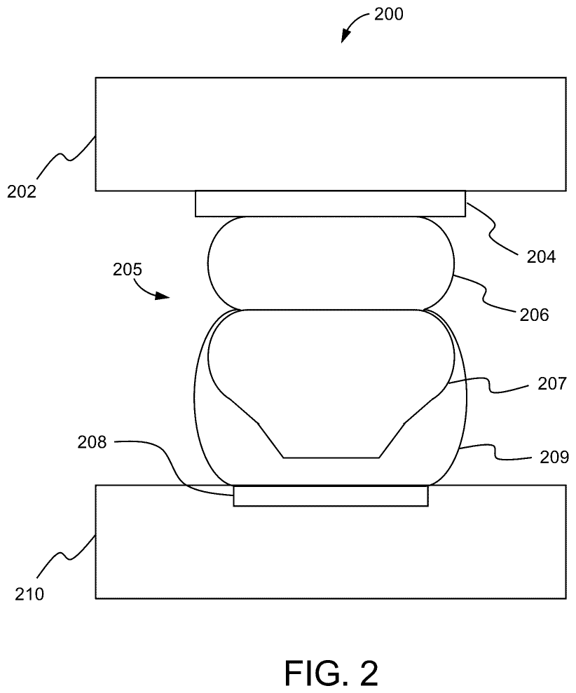

A conductive separating structure can be formed from multiple conductive elements, such as stud bumps. As depicted in FIG. 2, some integrated circuit devices can incorporate a stud bump assembly 200. In this assembly, a metal contact 204 on the surface of a semiconductor die 202 is attached to a contact 208 on the surface of a substrate 210 by a conductive separating structure 205. In this example, the conductive separating structure 205 comprises two stud bumps 206 and 207. The stud bump 207 is coated in solder paste 209 that attaches the structure to the contact 208, while the stud bump 206 prevents the solder paste from reaching the metal contact 204.

Stud bumps can be created by forming a sphere on the end of a wire, bonding the wire sphere to a surface by applying temperature or pressure, and then separating the newly formed stud bump from the wire. To form the double bump structures depicted in FIG. 2, this process can be repeated twice such that a second stud bump is bonded to a first stud bump that is already bonded to a metal contact. In some implementations of an integrated circuit device comprising stud bump assemblies, copper wire can be used to produce the stud bumps.

Some examples of an integrated circuit device can comprise a plurality of metal contacts and conductive separating structures. FIG. 3 depicts an example of an integrated circuit flip chip device 300 comprising several conductive separating structures 308A, 308B, 308C, and 308D connecting a semiconductor die 302 and a substrate 304. One end of each conductive separating structure is connected to a metal contact 306A, 306B, 306C, 306D arranged on the surface of the semiconductor die 302. Another end of each conductive separating structure is connected to a metal contact 310A, 310B, 310C, 310D that pass through the substrate 304. A contact-sensitive structure 312 is attached to the surface of the semiconductor die and is suspended in an air gap between the semiconductor die and the substrate. For clarity of illustration, only a small number of conductive separating structures are shown, but typically a large number of conductive separating structures would be arranged in a two dimensional array in a regular pattern or in an irregular pattern connecting the surfaces of the semiconductor die 302 and substrate 304, and there may be multiple areas where there are gaps surrounding contact-sensitive structures that have been fabricated over the surface of the semiconductor die (e.g., a die comprising a substrate composed of a semiconductor such as silicon (Si), indium phosphide (InP), or indium gallium arsenide (InGaAs), or a die comprising a substrate composed of some other material, such as a ceramic or organic material).

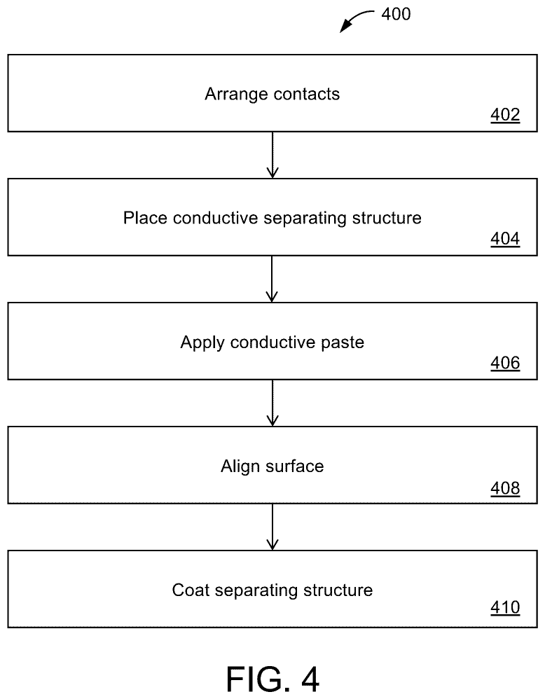

FIG. 4 shows an example process 400 for connecting a die and a substrate. The process 400 includes arranging (402) one or more metal contacts over a surface of the die, where the surface is substantially coplanar with a first plane. The process 400 further includes placing (404) a first end of a conductive separating structure into contact with one or more of the metal contacts, the conductive separating structure extending away from the first end along an axis that is substantially perpendicular to the first plane. The conductive separating structure intersects a second plane that is substantially parallel to the first plane at a first location along the axis such that an intersection of the conductive separating structure with the second plane forms a first curve enclosing a first area. The conductive separating structure also intersects a third plane that is substantially parallel to the first plane at a second location along the axis that is further from the first plane than from the second plane, such that an intersection of the conductive separating structure with the third plane forms a second curve enclosing a second area, wherein the first area is smaller than the second area. The process 400 includes applying (406) conductive paste onto a surface of the substrate and aligning (408) the surface of the substrate to be substantially parallel to the surface of the die, and contacting a second end of the conductive separating structure to the conductive paste. The process 400 includes coating (410) the conductive separating structure with the conductive paste such that the conductive paste coats a portion of the conductive separating structure between the second end and the second plane and not between the second plane and the first plane.

In some cases, the use of a conductive separating structure can be helpful to avoid chip connection techniques that comprise more process flow steps and produce devices with larger physical footprints, such as wirebonding. In wirebonding, one end of a wire is bonded to a metal contact and the other end is connected to external circuitry some distance away from the metal contact. Some integrated circuit devices comprise a semiconductor die with many metal contacts arranged on its surface. In such examples, connecting each of these metal contacts to external circuitry by wirebonding can be intensive, especially from the perspectives of device size and manufacturing time. From a device size perspective, each wirebond may require a minimum loop height to provide a strain relief structure, in addition to a length spanning the metal contact and external circuitry. Typical wirebonding implementations can comprise a fan out structure to incorporate the loop height and length of each wirebond, which can increase the physical device footprint and can increase the risk of damaging structures on the surface of the semiconductor die. Bonding and inspecting each end of a wirebond can also be intensive from a process flow perspective. Furthermore, this wirebond process may be relatively fragile, and failure inspection can involve individually checking each wirebonded connection. By using conductive separating structures and a flip chip manufacturing process, failure inspection can be more quickly conducted by batch failure tests and with automated defect sorting. For instance, batch failure tests can be performed by applying opposing stress to the semiconductor die and the substrate to check for any defective connections. Alternatively, x-ray imaging can be performed to check for defective connections.

While the disclosure has been described in connection with certain embodiments, it is to be understood that the disclosure is not to be limited to the disclosed embodiments but, on the contrary, is intended to cover various modifications and equivalent arrangements included within the scope of the appended claims, which scope is to be accorded the broadest interpretation so as to encompass all such modifications and equivalent structures as is permitted under the law.

What is claimed is:

1. An apparatus comprising:
a die having a surface over which one or more metal contacts are arranged, where the surface is substantially coplanar with a first plane;
a conductive separating structure with a first end in contact with at least one of the one or more metal contacts, the conductive separating structure extending away from the first end along an axis that is substantially perpendicular to the first plane and
(1) intersecting a second plane that is substantially parallel to the first plane at a first location along the axis such that an intersection of the conductive separating structure with the second plane forms a first curve enclosing a first area, and
(2) intersecting a third plane that is substantially parallel to the first plane at a second location along the axis that is further from the first plane than from the second plane, such that an intersection of the conductive separating structure with the third plane forms a second curve enclosing a second area,
wherein the first area is smaller than the second area;
a conductive paste coating a portion of the conductive separating structure between the second plane and a second end of the conductive separating structure and not between the second plane and the first plane; and
a substrate having a surface that is substantially parallel to the first plane, the substrate abutting the conductive paste at the second end of the conductive separating structure.

2. The apparatus of claim 1, wherein the conductive separating structure intersects a fourth plane that is substantially parallel to the first plane at a third location along the axis that is between the first plane and the first location such that an intersection of the conductive separating structure with the fourth plane forms a third curve enclosing a third area that is larger than the first area.

3. The apparatus of claim 1, further comprising a plurality of conductive separating structures such that each of the one or more metal contacts is in contact with a first end of at least one of the plurality of conductive separating structures.

4. The apparatus of claim 1, wherein one or more contact-sensitive structures are arranged on the surface of the die.

5. The apparatus of claim 4, wherein at least one of the one or more contact-sensitive structures has a first portion contacting the surface of the die and a second portion suspended in an air gap between the surface of the die and the surface of the substrate.

6. The apparatus of claim 1, wherein a portion of the conductive separating structure that is not coated in conductive paste is surrounded by air.

7. The apparatus of claim 1, wherein one or more of the metal contacts comprises gold.

8. The apparatus of claim 1, wherein the die comprises indium phosphide.

9. The apparatus of claim 1, wherein the conductive separating structure comprises copper.

10. The apparatus of claim 1, wherein the conductive paste comprises one or more metals that include tin.

11. The apparatus of claim 10, wherein the conductive paste does not include lead.

12. The apparatus of claim 1, wherein the conductive paste comprises one or more materials that do not cause embrittlement of any material in the conductive separating structure and that do cause embrittlement of at least one material in the one or more metal contacts.

13. The apparatus of claim 1, wherein the die and the substrate each have a coefficient of thermal expansion (CTE), and the CTE of the substrate and the CTE of the die are within 10% of each other.

14. A method of connecting a die and a substrate, the method comprising:
arranging one or more metal contacts over a surface of the die, where the surface is substantially coplanar with a first plane;
placing a first end of a conductive separating structure into contact with one or more of the metal contacts, the conductive separating structure extending away from the first end along an axis that is substantially perpendicular to the first plane and
(1) intersecting a second plane that is substantially parallel to the first plane at a first location along the axis such that an intersection of the conductive separating structure with the second plane forms a first curve enclosing a first area, and
(2) intersecting a third plane that is substantially parallel to the first plane at a second location along the axis that is further from the first plane than from the second plane, such that an intersection of the conductive separating structure with the third plane forms a second curve enclosing a second area,
wherein the first area is smaller than the second area;
applying conductive paste onto a surface of the substrate;
aligning the surface of the substrate to be substantially parallel to the surface of the die, and contacting a second end of the conductive separating structure to the conductive paste; and
coating the conductive separating structure with the conductive paste such that the conductive paste coats a portion of the conductive separating structure between the second end and the second plane and not between the second plane and the first plane.

15. The method of claim 14, wherein the conductive separating structure comprises two or more copper stud bumps.

16. The method of claim 14, wherein the conductive separating structure causes the surface of the die and the surface of the substrate to be separated by an air gap.

17. The method of claim 16, wherein a contact-sensitive structure on the surface of the die is suspended in the air gap.

18. The method of claim 14, wherein each of the one or more metal contacts is placed into contact with at least one conductive separating structure of a plurality of conductive separating structures.

19. The method of claim 14, wherein coating the conductive separating with the conductive paste comprises heating the conductive paste.

20. The method of claim 14, further comprising forming one or more contact-sensitive structures on the surface of the die prior to coating the conductive separating structure with the conductive paste.

21. An apparatus comprising:
a die having a surface over which one or more metal contacts are arranged and over which one or more contact-sensitive structures are arranged;
a plurality of conductive separating structures, each of the conductive separating structures
(1) comprising two or more stud bumps, and
(2) having a first stud bump of the two or more stud bumps in contact with at least one of the one or more metal contacts;
a conductive paste coating a portion of each of the conductive separating structures including at least a portion of a second stud bump of the two or more stud bumps; and
a substrate abutting the conductive paste at an end of the second stud bump.

22. The apparatus of claim 21, wherein at least one of the one or more contact-sensitive structures has a first portion contacting the surface of the die and a second portion suspended in an air gap between the surface of the die and a surface of the substrate.

23. The apparatus of claim 21, wherein a portion of each of the conductive separating structures that is not coated in conductive paste is surrounded by air.

24. The apparatus of claim 21, wherein one or more of the metal contacts comprises gold.

25. The apparatus of claim 21, wherein the die comprises indium phosphide.

26. The apparatus of claim 21, wherein the conductive separating structures comprise copper.

27. The apparatus of claim 21, wherein the conductive paste comprises one or more metals that include tin.

28. The apparatus of claim 27, wherein the conductive paste does not include lead.

29. The apparatus of claim 21, wherein the conductive paste comprises one or more materials that do not cause embrittlement of any material in the conductive separating structures and that do cause embrittlement of at least one material in the one or more metal contacts.

30. The apparatus of claim 21, wherein the die and the substrate each have a coefficient of thermal expansion (CTE), and the CTE of the substrate and the CTE of the die are within 10% of each other.
